(19) United States
(12) Patent Application Publication
(10) Pub. No.: US 2023/0393458 A1
(43) Pub. Date: Dec. 7, 2023

(54) METHOD FOR GENERATING MASK PATTERN

(71) Applicant: ASML NETHERLANDS B.V., Veldhoven (NL)

(72) Inventor: Jaiin MOON, San Jose, CA (US)

(73) Assignee: ASML NETHERLANDS B.V., Veldhoven (NL)

(21) Appl. No.: 18/031,865

(22) PCT Filed: Sep. 27, 2021
(86) PCT No.: PCT/EP2021/076501

§ 371 Date: Apr. 13, 2023

Related U.S. Application Data
(60) Provisional application No. 63/104,667, filed on Oct. 23, 2020.

(51) Int. Cl. G03F 1/36

(52) U.S. Cl. CPC G03F 1/36

(57) ABSTRACT

A method for generating a mask pattern for a patterning process. The method includes obtaining (i) a subset of target features (e.g., features too close) within a target pattern, the subset of target features having physical characteristic values below a threshold value, and (ii) an initial mask pattern (e.g., using an existing OPC process) associated with the target pattern; and modifying, based on a mask manufacturing constraint and a performance metric of the patterning process, one or more features of the initial mask pattern corresponding to the subset of target features to generate the mask pattern, the modifying including applying a curvature to a portion of the one or more features of the initial mask pattern.

### CROSS-REFERENCE TO RELATED APPLICATIONS

This application claims priority of U.S. application 63/104,667 which was filed on 23 Oct. 2020, and which is incorporated herein in its entirety by reference.

### TECHNICAL FIELD

The description herein relates to lithographic apparatuses, and more particularly to a tool and a method to generate mask pattern from a design layout, the mask pattern being used to pattern a substrate using the lithographic apparatus.

### BACKGROUND

A lithographic apparatus can be used, for example, in the manufacture of integrated circuits (ICs) or other devices. In such a case, a patterning device (e.g., a mask) may contain or provide a pattern corresponding to an individual layer of the device (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic apparatus, one target portion at a time. In one type of lithographic apparatus, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic apparatus will have a magnification factor M (generally <1), the speed F at which the substrate is moved will be a factor M times that at which the projection beam scans the patterning device.

Prior to the device fabrication procedure of transferring the pattern from the patterning device to the substrate of the device manufacturing process, the substrate may undergo various device fabrication procedures of the device manufacturing process, such as priming, resist coating and a soft bake. After exposure, the substrate may be subjected to other device fabrication procedures of the device manufacturing process, such as a post-exposure bake (PEB), development, and a hard bake. This array of device fabrication procedures is used as a basis to make an individual layer of a device, e.g., an IC. The substrate may then undergo various device fabrication procedures of the device manufacturing process such as etching, ion-implantation (doping), metallization, oxidation, chemo-mechanical polishing, etc., all intended to finish off the individual layer of the device. If several layers are required in the device, then the whole process, or a variant thereof, is repeated for each layer. Eventually, a device will be present in each target portion on the substrate. If there is a plurality of devices, these devices are then separated from one another by a technique such as dicing or sawing, whence the individual devices can be mounted on a carrier, connected to pins, etc.

So, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical or nanoimprint lithography using a lithographic apparatus, to provide a pattern on a substrate and typically, but optionally, involves one or more related pattern processing steps, such as resist development by a development apparatus, baking of the substrate using a bake tool, etching using the pattern using an etch apparatus, etc. Further, one or more metrology processes are typically involved in the patterning process.

### SUMMARY

In an embodiment, there is provided a method for generating a mask pattern for a patterning process. The method includes obtaining (i) a subset of target features within a target pattern, the subset of target features having physical characteristic values breaching (e.g., above or below) a threshold value, and (ii) an initial mask pattern associated with the target pattern. For example, the target pattern can be a portion of a design layout and the subset of target features can be design layout features that are too close (e.g., distance between edges of two features is out a design rule check). The method further includes modifying, based on a mask manufacturing constraint and a performance metric (e.g., EPE) of the patterning process, one or more features of the initial mask pattern (e.g., OPCed mask pattern) corresponding to the subset of target features to generate the mask pattern. The modifying comprising applying a curvature to a portion of the one or more features of the initial mask pattern. For example, mask features corresponding to the subset of target features are rounded.

Furthermore, in an embodiment, there is provided, a computer program product comprising a non-transitory computer readable medium having instructions recorded thereon, the instructions when executed by a computer implementing the method of any of the above claims.

Furthermore, in an embodiment, there is provided, non-transitory computer-readable medium for generating a mask pattern for use in a semiconductor manufacturing process by applying a curvature to particular features associated with a circuit pattern so constraints related to mask manufacturing processes and patterning processes are satisfied. The medium includes instructions stored therein that, when executed by one or more processors, cause operations including receiving a circuit pattern comprising a plurality of circuit features to be printed on a substrate, each circuit feature having a polygon shape outlines; identifying, from the plurality of circuit features, a first circuit feature and a second circuit feature that have a distance between their respective shape outlines below a distance threshold value; determining, by simulating a process model of a patterning process using the circuit pattern, an initial mask pattern associated with the circuit pattern, the initial mask pattern comprising a first mask feature and a second mask feature corresponding to the first circuit feature and the second circuit feature, respectively, the first mask feature and the second mask feature having polygon shape outlines different from their corresponding circuit features; determining whether the first mask feature and the second mask feature satisfy a mask manufacturing constraint, the mask manufacturing constraint comprising a criterion that limits a shape of a mask feature during the mask manufacturing process; responsive to the mask manufacturing constraint not being satisfied, modifying, based on a smallest distance between outlines of the first mask feature and the second mask feature, the initial mask pattern by applying a curvature to a portion of the first mask feature and/or the second mask feature causing an increase in the distance between the outlines of the first mask feature and the second mask feature; using the modified mask pattern, further simulating the process models of the patterning process to determine a simulated pattern of the patterning process; determining, by comparing the simulated pattern with the circuit pattern, a performance metric of the patterning process, the performance metric indicative of how closely the simulated pattern matches the circuit pattern; and responsive to the performance metric (e.g., EPE) not being within a performance threshold, applying a further curvature to the first mask feature and/or the second mask feature causing the performance metric to be within the within the performance threshold, while maintaining the smallest distance between outlines of the first mask feature and the second mask feature within the mask manufacturing constraint.

The foregoing general description of the illustrative implementations and the following detailed description thereof are merely exemplary aspects of the teachings of this disclosure, and are not restrictive.

### BRIEF DESCRIPTION OF FIGURES

The accompanying drawings, which are incorporated in and constitute a part of the specification, illustrate one or more embodiments and, together with the description, explain these embodiments. The accompanying drawings have not necessarily been drawn to scale. Any values dimensions illustrated in the accompanying graphs and figures are for illustration purposes only and may or may not represent actual or preferred values or dimensions. Where applicable, some or all features may not be illustrated to assist in the description of underlying features. In the drawings:

FIG. 1 is a block diagram of various subsystems of a lithography system according to an exemplary embodiment of the present disclosure.

FIG. 2 schematically depicts an embodiment of a lithographic cell or cluster according to an exemplary embodiment of the present disclosure.

FIG. 3 schematically depicts a method of placing assist features (assist features connected to main features or independent assist features) into a design layout according to an exemplary embodiment of the present disclosure.

FIG. 4 is a pictorial representation of an exemplary target pattern (e.g., a desired pattern to be printed on a substrate), according to an embodiment of the present disclosure.

FIG. 5A is a pictorial representation of an initialization step of an existing mask generation process, where the dotted outlines around target features are starting shapes of an initial mask pattern that are subsequently modified to generate the final mask pattern, according to an embodiment of the present disclosure.

FIG. 5B is a pictorial representation of an intermediate step of the existing mask generation process, where the dotted outlines around target features are intermediate shapes of an mask pattern that are subsequently modified to generate the final mask pattern, according to an embodiment of the present disclosure.

FIG. 5C is a pictorial representation of a final step of the existing mask generation process, where the dotted outlines around target features are final shapes of the mask, according to an embodiment of the present disclosure.

FIG. 6 is a flowchart of an example mask generation process, according to an embodiment of the present disclosure.

FIG. 7 is a pictorial representation of an exemplary target pattern having very close target features (e.g., violates design rules), according to an embodiment of the present disclosure.

FIG. 8 is a pictorial representation of an exemplary target pattern with a subset of target feature marked for further modification according to the method of FIG. 6, according to an embodiment of the present disclosure.

FIG. 9 illustrates an example final mask pattern, the final mask pattern being overlaid with target features and simulated contour, according to an embodiment of the present disclosure.

FIG. 10 is an example distribution of edge placement error associated with a patterned substrate that is patterned using a mask pattern generated using an existing method (e.g., FIGS. 5A-according to an embodiment.

FIG. 11 is an example distribution of edge placement error associated with a patterned substrate that is patterned using a mask pattern generated using the present method (e.g., FIG. 6), according to an embodiment.

FIG. 12 is a flowchart of another method of generating a mask pattern, according to an embodiment.

FIG. 13 is a flow chart for a method for determining an aspect of a patterning process using the mask pattern generated according to FIG. 6, according to an exemplary embodiment of the present disclosure.

FIG. 14 is a block diagram of an example computer system according to an exemplary embodiment of the present disclosure.

FIG. 15 is a schematic diagram of a lithographic projection apparatus according to an exemplary embodiment of the present disclosure.

FIG. 16 is a schematic diagram of an extreme ultra violet (EUV) lithographic projection apparatus according to an exemplary embodiment of the present disclosure.

FIG. 17 is a more detailed view of the apparatus in FIG. 13 according to an exemplary embodiment of the present disclosure.

FIG. 18 is a more detailed view of the source collector module SO of the apparatus of FIGS. 16 and 17, according to an embodiment.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

The description set forth below in connection with the appended drawings is intended as a description of various embodiments of the disclosed subject matter and is not necessarily intended to represent the only embodiment(s). In certain instances, the description includes specific details for the purpose of providing an understanding of the disclosed embodiment(s). However, it will be apparent to those skilled in the art that the disclosed embodiment(s) may be practiced without those specific details. In some instances, well-known structures and components may be shown in block diagram form in order to avoid obscuring the concepts of the disclosed subject matter.

As semiconductor or other device manufacturing processes continue to advance, the dimensions of functional elements have continually been reduced while the amount of functional elements, such as transistors, per device has been steadily increasing over decades, following a trend commonly referred to as “Moore's law”. At the current state of technology, layers of devices are manufactured using lithographic apparatuses that project a design layout onto a substrate using illumination from a deep-ultraviolet (e.g., 193 nm) illumination source or an extreme-ultraviolet (e.g., 13.52 nm) illumination source, creating individual functional elements having dimensions well below nm.

This process in which features with dimensions smaller than the classical resolution limit of a lithographic apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic apparatus or the design layout. These include, for example, but not limited to, optimization of NA and optical coherence settings, customized illumination schemes, use of phase shifting patterning devices, optical proximity correction (OPC) in the design layout, or other methods generally defined as “resolution enhancement techniques” (RET).

As an example of RET, OPC addresses the fact that the final size and placement of an image of the design layout projected on the substrate will not be identical to, or simply depend only on the size and placement of the design layout on the patterning device. It is noted that the terms “mask”, “reticle”, “patterning device” are utilized interchangeably herein. Also, person skilled in the art will recognize that, the term “mask,” “patterning device” and “design layout” can be used interchangeably, as in the context of RET, a physical patterning device is not necessarily used but a design layout can be used to represent a physical patterning device. For the small feature sizes and high feature densities present on some design layout, the position of a particular edge of a given feature will be influenced to a certain extent by the presence or absence of other adjacent features. These proximity effects arise from minute amounts of radiation coupled from one feature to another or non-geometrical optical effects such as diffraction and interference. Similarly, proximity effects may arise from diffusion and other chemical effects during post-exposure bake (PEB), resist development, and etching that generally follow lithography.

In order to increase the chance that the projected image of the design layout is in accordance with requirements of a given target circuit design, proximity effects may be predicted and compensated for, using sophisticated numerical models, corrections or pre-distortions of the design layout. The article “Full-Chip Lithography Simulation and Design Analysis—How OPC Is Changing IC Design”, C. Spence, Proc. SPIE, Vol. 5751, pp 1-14 (2005) provides an overview of current “model-based” optical proximity correction processes. In a typical high-end design almost every feature of the design layout has some modification in order to achieve high fidelity of the projected image to the target design. These modifications may include shifting or biasing of edge positions or line widths as well as application of “assist” features that are intended to assist projection of other features.

One of the simplest forms of OPC is selective bias. Given a CD vs. pitch curve, all of the different pitches could be forced to produce the same CD, at least at best focus and exposure, by changing the CD at the patterning device level. Thus, if a feature prints too small at the substrate level, the patterning device level feature would be biased to be slightly larger than nominal, and vice versa. Since the pattern transfer process from patterning device level to substrate level is non-linear, the amount of bias is not simply the measured CD error at best focus and exposure times the reduction ratio, but with modeling and experimentation an appropriate bias can be determined. Selective bias is an incomplete solution to the problem of proximity effects, particularly if it is only applied at the nominal process condition. Even though such bias could, in principle, be applied to give uniform CD vs. pitch curves at best focus and exposure, once the exposure process varies from the nominal condition, each biased pitch curve will respond differently, resulting in different process windows for the different features. A process window being a range of values of two or more process parameters (e.g., focus and radiation dose in the lithographic apparatus) under which a feature is sufficiently properly created (e.g., the CD of the feature is within a certain range such as ±10% or ±5%). Therefore, the “best” bias to give identical CD vs. pitch may even have a negative impact on the overall process window, reducing rather than enlarging the focus and exposure range within which all of the target features print on the substrate within the desired process tolerance.

Other more complex OPC techniques have been developed for application beyond the one-dimensional bias example above. A two-dimensional proximity effect is line end shortening. Line ends have a tendency to “pull back” from their desired end point location as a function of exposure and focus. In many cases, the degree of end shortening of a long line end can be several times larger than the corresponding line narrowing. This type of line end pull back can result in catastrophic failure of the devices being manufactured if the line end fails to completely cross over the underlying layer it was intended to cover, such as a polysilicon gate layer over a source-drain region. Since this type of pattern is highly sensitive to focus and exposure, simply biasing the line end to be longer than the design length is inadequate because the line at best focus and exposure, or in an underexposed condition, would be excessively long, resulting either in short circuits as the extended line end touches neighboring structures, or unnecessarily large circuit sizes if more space is added between individual features in the circuit. Since one of the goals of integrated circuit design and manufacturing is to maximize the number of functional elements while minimizing the area required per chip, adding excess spacing is an undesirable solution.

Two-dimensional OPC approaches may help solve the line end pull back problem. Extra structures (also known as “assist features”) such as “hammerheads” or “serifs” may be added to line ends to effectively anchor them in place and provide reduced pull back over the entire process window. Even at best focus and exposure these extra structures are not resolved but they alter the appearance of the main feature without being fully resolved on their own. A “main feature” as used herein means a feature intended to print on a substrate under some or all conditions in the process window. Assist features can take on much more aggressive forms than simple hammerheads added to line ends, to the extent the pattern on the patterning device is no longer simply the desired substrate pattern upsized by the reduction ratio. Assist features such as serifs can be applied for many more situations than simply reducing line end pull back. Inner or outer serifs can be applied to any edge, especially two dimensional edges, to reduce corner rounding or edge extrusions. With enough selective biasing and assist features of all sizes and polarities, the features on the patterning device bear less and less of a resemblance to the final pattern desired at the substrate level. In general, the patterning device pattern becomes a pre-distorted version of the substrate-level pattern, where the distortion is intended to counteract or reverse the pattern deformation that will occur during the manufacturing process to produce a pattern on the substrate that is as close to the one intended by the designer as possible.

Another OPC technique involves using completely independent and non-resolvable assist features, instead of or in addition to those assist features (e.g., serifs) connected to the main features. The term “independent” here means that edges of these assist features are not connected to edges of the main features. These independent assist features are not intended or desired to print as features on the substrate, but rather are intended to modify the aerial image of a nearby main feature to enhance the printability and process tolerance of that main feature. These assist features (often referred to as “scattering bars” or “SBAR”) can include sub-resolution assist features (SRAF) which are features outside edges of the main features and sub-resolution inverse features (SRIF) which are features scooped out from inside the edges of the main features. The presence of a SBAR adds yet another layer of complexity to a patterning device pattern. A simple example of a use of scattering bars is where a regular array of non-resolvable scattering bars is drawn on both sides of an isolated line feature, which has the effect of making the isolated line appear, from an aerial image standpoint, to be more representative of a single line within an array of dense lines, resulting in a process window much closer in focus and exposure tolerance to that of a dense pattern. The common process window between such a decorated isolated feature and a dense pattern will have a larger common tolerance to focus and exposure variations than that of a feature drawn as isolated at the patterning device level.

An assist feature may be viewed as a difference between features on a patterning device and features in the design layout. The terms “main feature” and “assist feature” do not imply that a particular feature on a patterning device must be labeled as one or the other.

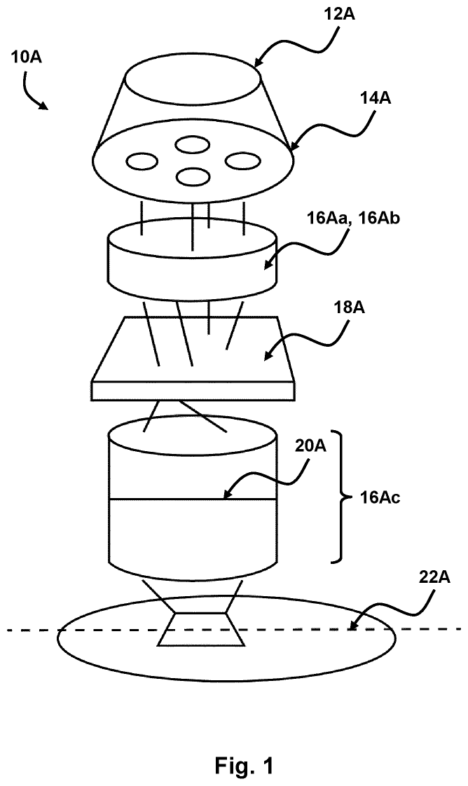

As a brief introduction, FIG. 1 illustrates an exemplary lithographic projection apparatus 10A. Major components include illumination optics which define the partial coherence (denoted as sigma) and which may include optics 14A, 16Aa and 16Ab that shape radiation from a radiation source 12A, which may be a deep-ultraviolet excimer laser source or other type of source including an extreme ultra violet (EUV) source (as discussed herein, the lithographic projection apparatus itself need not have the radiation source); and optics 16Ac that project an image of a patterning device pattern of a patterning device 18A onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=sin(Θₘₐₓ).

In a lithographic projection apparatus, projection optics direct and shape the illumination from a source via a patterning device and onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety

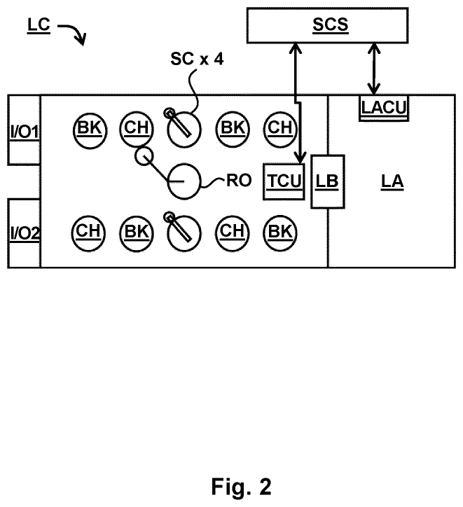

As shown in FIG. 2, the lithographic apparatus LA may form part of a lithographic cell LC, also sometimes referred to as a lithocell or lithocluster, which also includes apparatus to perform one or more pre- and post-exposure processes on a substrate. Conventionally these include one or more spin coaters SC to deposit a resist layer, one or more developers DE to develop exposed resist, one or more chill plates CH and one or more bake plates BK. A substrate handler, or robot, RO picks up a substrate from input/output ports I/O1, I/O2, moves it between the different process devices and delivers it to the loading bay LB of the lithographic apparatus. These devices, which are often collectively referred to as the track, are under the control of a track control unit TCU which is itself controlled by the supervisory control system SCS, which also controls the lithographic apparatus via lithographic control unit LACU. Thus, the different apparatus may be operated to maximize throughput (e.g., substrates processed per unit time) and processing efficiency. The lithographic cell LC may further comprises one or more etchers to etch the substrate and one or more measuring devices configured to measure a parameter of the substrate. The measuring device may comprise an optical measurement device configured to measure a physical parameter of the substrate, such as a scatterometer, a scanning electron microscope, etc. The measuring device may be incorporated in the lithographic apparatus LA. An embodiment of the present disclosure may be implemented in or with the supervisory control system SCS or the lithographic control unit LACU. For example, data from the supervisory control system SCS or the lithographic control unit LACU may be used by an embodiment of the present disclosure and one or more signals from an embodiment of the present disclosure may be provided to the supervisory control system SCS or the lithographic control unit LACU.

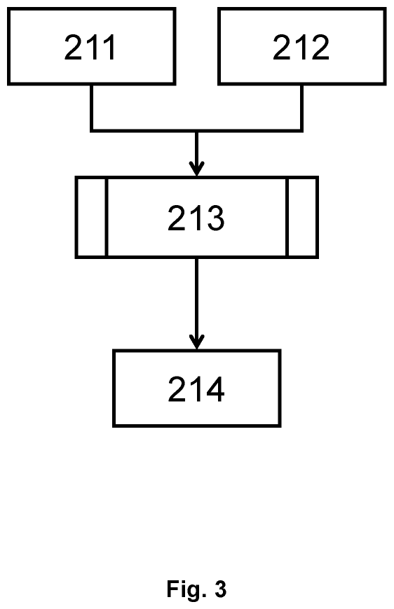

FIG. 3 schematically depicts a method of making optical proximity corrections 214 in a design layout (also referred as a target layout). The design layout may be a design layout before application of a RET or a design layout after application of a RET. The design layout may be binary or continuous tone. For example, the binary tone includes values 0 or 1 indicative to absence of presence of a feature in the design layout. While, the continuous tone includes values between 0 to 1 (e.g., 0, 0.2, 0.3, . . . , 1). In this disclosure, focus is made on placing assist features (assist features connected to main features or independent assist features) into a design layout as an example optical proximity correction to which the techniques herein can be applied. As will be appreciated, the techniques herein can be applied to alternative optical proximity corrections than assist features (such as bias, etc.) or applied to optical proximity corrections in addition to assist features (e.g., a combination of bias and assist features).

A computational or an empirical model 213 can be used to apply (e.g., determining one or more characteristics, such as the existence, location, type, shape, etc., of) one or more optical proximity corrections such as one or more assist features. The model 213 can take into account one or more characteristics 211 (also referred to as a processing parameter) of the device manufacturing process, or one or more design layout parameters 212, or both. The one or more processing parameters 211 are one or more parameters associated with the device manufacturing process but not with the design layout. For example, the one or more processing parameters 211 may include a characteristic of the illumination (e.g., intensity, pupil profile, etc.), a characteristic of the projection optics, dose, focus, a characteristic of the resist, a characteristic of development of the resist, a characteristic of post-exposure baking of the resist, or a characteristic of etching. The one or more design layout parameters 212 may include one or more shapes, sizes, relative locations, or absolute locations of various features on a design layout, and also overlapping of features on different design layouts. In an empirical model, the image (e.g., resist image, optical image, etch image) is not simulated; instead, the empirical model makes an optical correction (e.g., places an assist feature) based on a correlation between the input (e.g., the one or more processing parameters 211 or the design layout parameters 212) and the optical proximity correction. In a computational model, a portion or a characteristic of the image is calculated, and the optical proximity correction is applied based on the portion or the characteristic of the calculated image.

Typically, a design layout (e.g., a target layout) has billions of patterns and a sample of such patterns must be chosen for determining patterning process parameter, training process models, etc. So, it is desirable to choose diverse patterns that are representative of the design layout for determining process condition and mask patterns. Also, if similar target patterns exists across the target layout, then it is desirable to have similar mask patterns for improved consistency in mask manufacturing as well as process condition selection for the patterning process.

With reducing node size, a target pattern (e.g., logic circuit patterns) also referred as a design pattern desired to be printed on a chip comprises target features that are getting very small e.g., single nanometer in size. Today, lot of circuit designs are faced with tight design rules where several regions of the target pattern have no room for optical proximity corrections (OPC) to grow out because circuit features are too close to each other.

In current mask pattern generation process (e.g., employing OPC process), an amount of correction applied to target features (e.g., small sized features with small spaces between the target features) is limited by mask manufacturing limitations referred as Mask Rule Constraint (MRC). MRC defines geometric constraints associated with mask features that limits manufacturing of the mask features. For example, the geometric constraints can be a size (e.g., critical dimension) of a mask feature, a distance between two mask features, etc.

In an existing method for mask pattern generation, OPC generates Manhattanized polygon shapes. The Manhattanized polygon shapes that satisfy MRC pose limitations on the accuracy of printing the target features to be printed on the substrate. For example, MRC limits OPC in a region of a target pattern having small corner-to-corner space (e.g., less than 10 nm) between adjacent target features. In order to overcome this limitation, in the existing technology, OPC uses a corner cutting method to avoid the MRC violations without sacrificing OPC accuracy.

The corner cut method is used because of the limitation in existing mask pattern editing software and mask manufacturing capability. In the corner cut method, a 45° cut is made at a corner of a target feature relative to the sides of the target feature. The 45° corner cut satisfies MRC constraint between corners of two mask features. In addition to satisfying the MRC constraint, the resulting shape of the mask pattern, certain level of OPC inaccuracy may be avoided. However, the corner-cut method leaves a patterning process with smaller process variation (e.g., exposure or focus variation) margins.

Recently, with more advanced mask pattern generation method such as a freeform method (also referred as inverse OPC method), which allows a mask feature shape be more of a freeform shape. Such freeform approach ensures MRC is satisfied. However, the freeform method requires all the pattern in the mask to be freeform and limit its usability. Further freeform method results in different curvilinear shapes of each feature for different instances of the same target pattern. As such, mask patterns may be inconsistent and increase mask manufacturing time and cost, at times making curvilinear masks practically infeasible.

In the present disclosure, the above problems can be addressed by a method for improving mask pattern generation described herein. The method herein not only improves the mask manufacturing process but also ensures improved process variation margins for patterning process. Additionally, the mask pattern generated by the present method can be more consistent for same target pattern thereby substantially improving the mask manufacturing process time and cost. The present method can be easily integrated into e.g., a Manhattanized mask pattern generation methods.

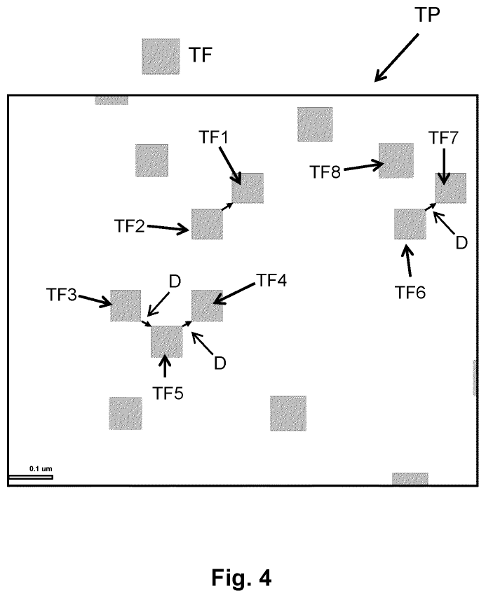

FIG. 4 is a pictorial representation of an example target pattern TP. The target pattern TP can be provided as a GDS file. The target pattern TP comprises polygon shapes referred as target features. For example, the target features are outlines of the gray shapes. FIG. 4 only marks few the target features TF1, TF2, TF3, TF4, TF5, TF6, TF7, and TF8 for explaining the concepts herein. The target features TF1-TF8 are spaced apart according to, e.g., a circuit design specification. However, some polygon shape outlines are too close to each other leaving very little room for corresponding mask features to grow. Further, growing the polygon shapes for making mask pattern further bring the features close to each other. As such, some mask features may not be manufactured or manufactured with only reduced accuracy via the mask manufacturing apparatus. In the present disclosure, such close target features are identified and modified as discussed herein. For example, target features that have a distance between the polygon shapes below a distance threshold should to be identified.

In the present example target pattern TP, polygon shape outlines of the target features TF1 and TF2 have a corner-to-corner distance of D (e.g., a smallest distance between the polygon shapes), which is below a desired distance threshold (e.g., 10 nm). The distance threshold can be a predetermined number. In an embodiment, the distance threshold may be determined based on heuristics, a relationship between spaces of target features and corresponding spaces of mask features, a function of a mask feature size and EPE, etc.

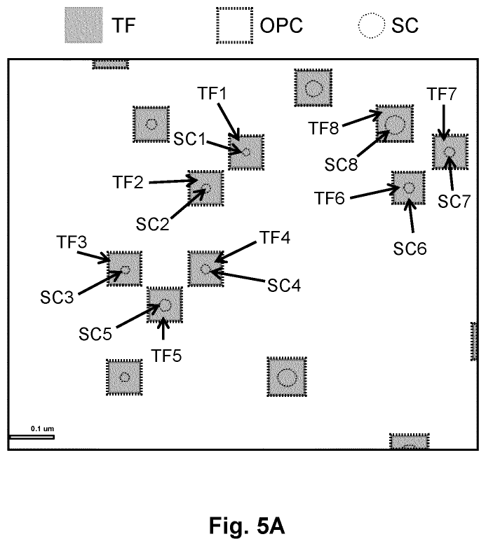

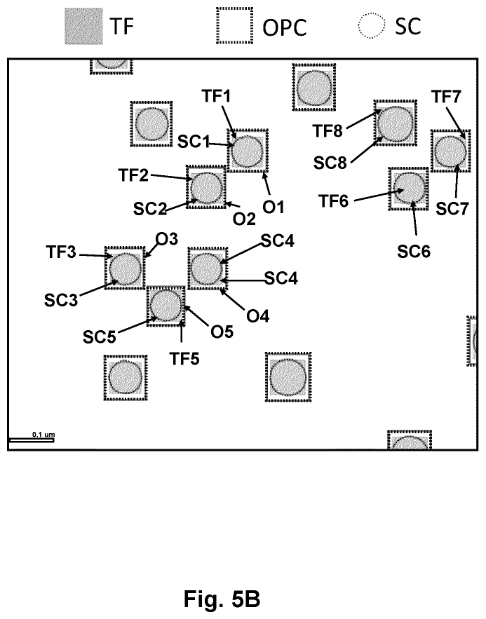

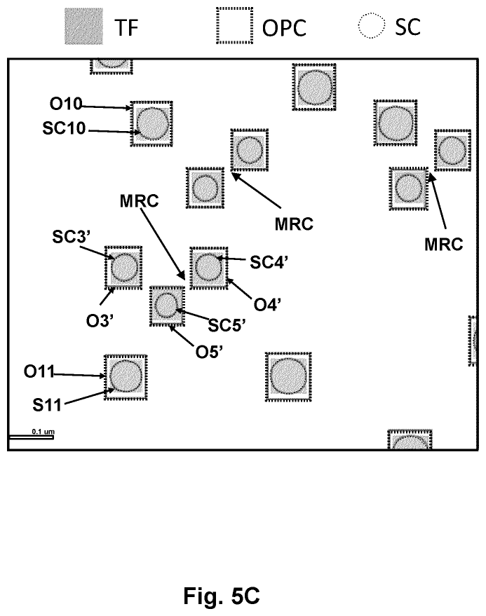

FIGS. 5A-5C illustrate limitation of the existing method of a mask pattern generation using the target pattern TP (of FIG. 4). The mask pattern generation process is an iterative process, where the polygon shape of target features are continuously transformed to generate mask features. In an example, such transformation of a target feature to a mask feature ensures that a pattern to be printed on a substrate will closely match the target feature. Example mask optimization processes such as OPC are discussed herein throughout the disclosure.

FIG. 5A is illustrate initialization of the mask generation process. In the present example, an optical proximity correction (OPC) process is employed. In an example OPC process, one or more process model (e.g., see FIG. 2) are executed to generate a simulated pattern corresponding to a mask pattern. If the simulated pattern does not closely match the target pattern (e.g., EPE not within desired EPE threshold), then the mask pattern is modified. Accordingly, the features of the mask pattern are also referred as OPCed features or post OPC features. In FIG. 5A, the OPC starts, where initial OPC features are illustrated by dotted outlines around the target features. For example, for illustration purposes, initial OPC features (dotted outer shapes around target features) are overlaid around on the target features TF1, TF2, and TF4. For the OPC features, the corresponding simulated features on the substrate are generated via the OPC simulation. For example, for illustration purposes, simulated features are shown as simulated contours SC1, SC2, SC3, SC4, SC5, SC6, SC7, and SC8 (dotted inner shapes inside the target features). These simulated contours have substantially circular shape and do not closely match the corresponding polygon shape of the target features (e.g., TF1-TF8). For example, the difference between the polygon shape outlines of the target features and simulated circular shapes is above a desired difference threshold.

The OPC process modifies, in an iterative manner, the OPC features by changing the size and shape of the initial OPC features to cause the OPC features generate the simulated features that closely match the target pattern. In the present example, Manhattanized OPC features are generated, where the Manhattanized OPC features have substantially rectangular shapes. For example, as shown in FIG. 5B, the initial OPC features are grown out in size. These grown out OPC features (e.g., O1, O2, O3, O4, and O5) cause the circular outlines of the simulated features (e.g., SC1-SC5) to closely match the polygon shape outlines of the corresponding target features (e.g., TF1-TF5). For example, a difference between each simulated contour and each corresponding target feature contour is within a desired edge placement threshold. As such, a performance metric (e.g., EPE) of a patterning process employing the post OPC mask pattern (in FIG. 5B) is within the desired performance threshold.

However, some OPC features of FIG. 5B are too close to each other resulting in violation of mask manufacturing limitations (e.g., MRC). For example, MRC comprises checking a space between OPC features, a width of the OPC feature, a corner-to-corner distance between OPC features, or other geometric constraint are within their respective threshold values. In other words, when MRC constraints are violated, those OPC features may not be accurately manufactured via a mask manufacturing apparatus that will affect the performance metric of the patterning process. For example, MRC violation occurs between OPC features such as O1 and O2, O3 and O5, and O4 and O5. For example, a corner-to-corner distance between OPC features (e.g., O1 and O2) is less than 2 nm, which is less than a distance threshold of e.g., 8 nm of MRC. These OPC features correspond to the target features that are too close (e.g., below a distance threshold), as discussed earlier.

Referring to FIG. 5C, the mask pattern is further modified to satisfy the MRC constraints. For example, OPC features are reduced in size. For example, OPC features O3′, O4′ and O5′ are smaller than the corresponding OPC features O3, O4, and O5, respectively of FIG. 5B. The OPC features O3, O4, and O5 are modified, for example, based on the corner-to-corner check and space check to cause the OPC features to satisfy the MRC constraints. However, the MRC related modification of OPC features (e.g., O3′, O4′ and O5′) causes the simulated pattern on the substrate to miss the performance specification of the patterning process. For example, the OPC features O3′, O4′ and O5′ causes generation of simulated features SC3′, SC4′ and SC5′ which do not closely match the corresponding target features TF3, TF4, and TF5, respectively. For example, a difference between each simulated feature contour and each corresponding target feature contour is below an edge placement threshold value.

So, if MRC constraints are satisfied, the performance threshold (e.g., EPE threshold) of the patterning process may not be met. In other words, once MRC is honored, EPE issue may arise, for example. With existing OPC process, even if the OPC features are further modified to try to cause simulated features to hit the target features, MRC restriction may not be met. Thus, limiting the performance of the patterning process and/or the mask manufacturing process.

As shown in FIG. 5C, regions of target pattern that does not have tight spaces, several OPC features (e.g., O10 and O11) satisfy the performance specification (e.g., simulated contours SC10 and SC11 closely match corresponding target feature contours) of the pattern process with no MRC issues. While, some of the OPC features (e.g., O1′, O2′, O3′, O4′, O5′) associated with tight regions within the target pattern do not meet the performance specification of the patterning process when MRC is satisfied.

In the present disclosure, there is provided a solution to solve the above problem. For example, the method 600 identifies target features having tight gaps (e.g., below a distance threshold) therebetween, and during the OPC process, force the OPC feature to take a curved shape.

In the present method, for example, during OPC when OPCed mask features encounter corner-to-corner MRC related correction, the correction for such corners involve applying a curvature (e.g., rounding) to the mask feature to avoid the MRC violation and still keep the process window margin without using more computational power. In some embodiments only portions of the mask pattern encountering the MRC violation are rounded with this method so that it mask manufacturing process is much easier than, for example, freeform OPC method.

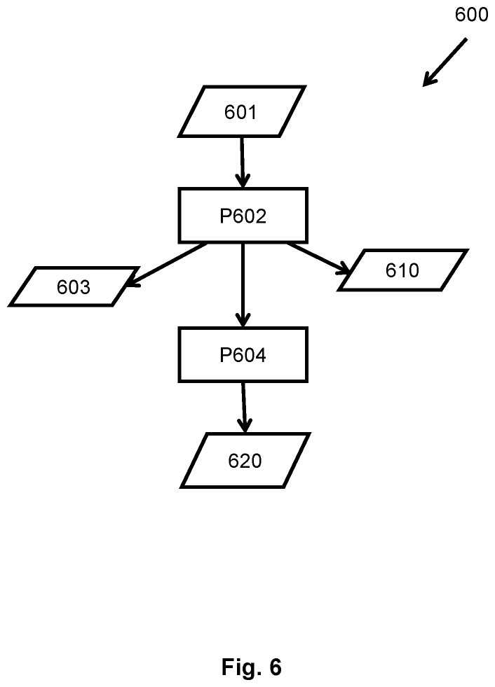

FIG. 6 is a flow chart of a method for generating a mask pattern, according to an embodiment of the present disclosure. The method 600 includes processes P602 and P604.

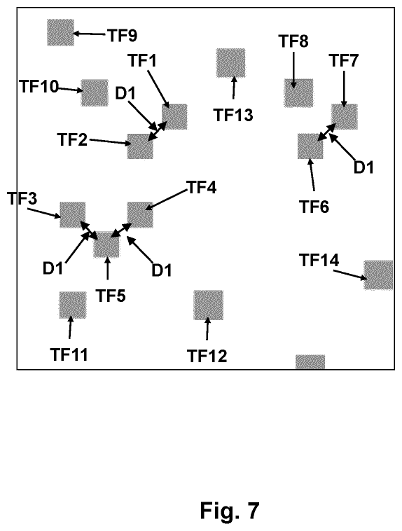

Process P602 includes obtaining (i) a subset of target features 603 within a target pattern 601, the subset of target features 603 having physical characteristic values breaching (e.g., above or below) a threshold value, and (ii) an initial mask pattern 610 associated with the target pattern 601. In an embodiment, the physical characteristic associated with the subset of target features comprises, but not limited to, a size of the polygon, a distance target features, a corner-to-corner distance between adjacent features, an offset between adjacent target features, etc. Example of the subset of target features (e.g., T1-T7) are illustrated in FIG. 7. For example, in FIG. 7, the physical characteristic value is a corner-to-corner distance between two adjacent features.

FIG. 7 illustrates an example target pattern (e.g., similar to that in FIG. 5A) having tight spaces (e.g., a distance between features being below a distance threshold). The target pattern includes target features TF1-TF14, with distance between the target features being high or small depending on the circuit design specification. For example, in FIG. 7, target features TF1 and TF2, TF3 and TF5, TF4 and TF5 have a distance D1, which is below a distance threshold. These distances D1 characterize tight spaces, for example, within a GDS file (having polygon shapes of target pattern) that have a small corner-to-corner space and tags such polygons. During the OPC only such tagged polygon are modified in a particular manner different from the existing Manhattanized shape.

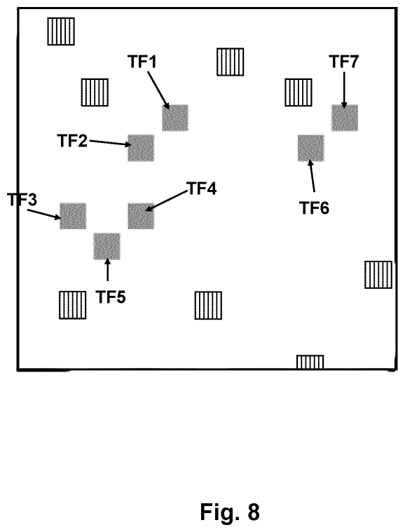

FIG. 8 is a pictorial representation of a subset of target feature identified within the target pattern (of FIG. 7), according to an embodiment. For example, a subset of target feature TF1-TF7 are marked for visual representation. In an embodiment, the subset of target features are identified based on corner-to-corner distance between the polygon shape outlines of the target features being below a threshold value (e.g., 10 nm). The present disclosure is not limited to corner-to-corner distance, and other geometric relations between target features or geometric size or shape may be used to determine subset of target features of interest (during the mask pattern generation process). In an embodiment, such identification rules may be implemented in an existing software implementing, e.g., OPC process.

Referring back to FIG. 6, in an embodiment, the obtaining of the initial mask pattern 610 includes simulating a mask optimization process (e.g., MO, SMO, OPC, etc., as discussed herein) using the target pattern 601 to generate a mask pattern that causes a simulated pattern on a substrate to closely match the target pattern 601. In an embodiment, the initial mask pattern can be any intermediate mask pattern obtained during simulation of the mask optimization process. An example initial mask pattern is illustrated in FIG. 5B.

Process P604 includes modifying, based on mask manufacturing constraints and a performance metric of the patterning process, one or more features of the initial mask pattern 610 corresponding to the subset of target features 603 to generate the mask pattern 620. The modifying comprising applying a curvature to a portion of the one or more features of the initial mask pattern 610. In an embodiment, the performance metric comprises an edge placement error between the simulated pattern and the target pattern 601.

In an embodiment, the modifying of the initial mask pattern 610 includes simulating the mask optimization process to modify a geometry of the one or more features of the initial mask pattern 610 corresponding to the subset of target features 603. In an embodiment, the mask optimization process comprises an optical proximity correction process.

In an embodiment, the simulating of the mask optimization process (e.g., MO, SMO, OPC, etc. discussed herein) is an iterative process, each iteration comprising: simulating, via one or more process model using the initial mask pattern 610, the patterning process to generate a simulated pattern on a substrate; determining, based on the simulated pattern and the target pattern 601, the performance metric associated with the patterning process; determining whether the performance metric is within a performance threshold; and modifying the geometry of the one or more features of the initial mask pattern 610 corresponding to the subset of target features 603 until the modified mask pattern causes the performance metric to be within the performance threshold. In an embodiment, the mask optimization process is limited to modifying of the main features corresponding to the target layout, and not assist features. However, the present disclosure is not limited to main features. In an embodiment, the assist features may be affected due to changes in the main features.

In an embodiment, features of the initial mask pattern 610 are Manhattanized features of the target pattern 601, and the one or more features of the modified mask pattern are curvilinear while the remaining features are unchanged Manhattanized features of the initial mask pattern 610. In an embodiment, features of the initial mask pattern 610 are curvilinear in shape, and the one or more features of the modified mask pattern are curvilinear while remaining features are unchanged curvilinear features of the initial mask pattern 610.

In an embodiment, the method 600 further includes determining, via simulating a process model (e.g., see FIG. 3) using the mask pattern, a process condition associated the patterning process; and exposing, via a lithographic apparatus configured according to the process condition and employing the mask comprising the mask pattern. In an embodiment, the process condition includes values of one or more of process parameters including dose, focus, illumination intensity, and/or illumination pupil.

During the mask pattern generation, mask features corresponding to the subset of target features may be modified in a particular manner, as discussed herein. For example, by applying a curvature to satisfy MRC and a performance metric of the patterning process.

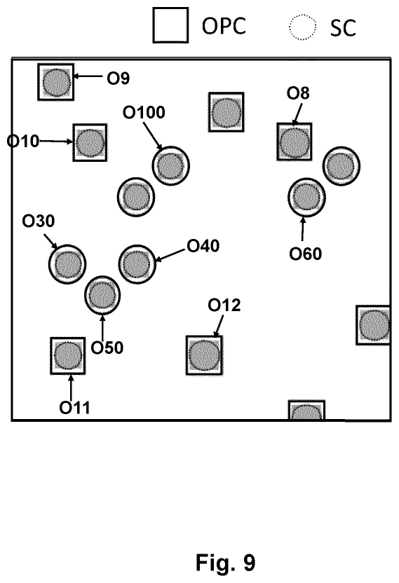

FIG. 9 is illustrate an example OPC features corresponding to the subset of target features generated according to the present disclosure. The mask pattern in FIG. 9 is a final mask pattern after modifying an initial mask pattern that included features as shown in FIG. 5B or FIG. 5C, for example. For example, an initial mask pattern was obtained via the OPC process, as discussed with respect to FIG. 5B. Then, according to an embodiment of present disclosure, when the MRC violations occur, particularly at the identified mask features corresponding to the subset of target features TF1-TF7, only those mask features are modified to substantially circular features, e.g., O30, O40, O50, O60, O100 are the OPC features that are rounding. These rounded OPC features correspond to the subset of target features TF1, TF3, TF4, TF5, and TF6, for example. The other mask features of the initial mask pattern maintain their original shape. For example, OPC features O9-O12 have a rectangular polygon shape (similar to the initial OPC features of FIG. 5B or FIG. 5C).

In an embodiment, the process of FIG. 9 can be implemented for example via a processor configured to include instructions to identify the subset of the target pattern, tag an identifier to such subset of the target pattern, determine whether any MRC violations occur at the tagged subset of target features, and responsive to any violations, performing a rounding operation of those features. For example, the rounding operation may performing rounding of only a portion of the initial mask feature, rounding of a corner of the mask feature, or rounding of the entire mask feature. For example, the rounding can be performed by applying a curvature of a predetermined radius. The radius may be determined based on heuristic, stored in a table or dynamically determined during the OPC process to ensure a performance metric is also satisfied. In an embodiment, an amount of curvature (e.g., radius) to be applied to a subset of OPC features (that correspond to the identified subset of target features) can be a function space between adjacent features.

Such rounding of the OPC features (e.g., O100, O30, O40, O50) ensures that the MRC constraints are satisfied. For example, the curvature can be manufactured via the mask manufacturing apparatus. Also, the applied curvature causes the simulated contours on the substrate to substantially match the target feature contours. As such, the performance metric (e.g., EPE) of the patterning process is satisfied by such curved mask features.

In an embodiment, each mask feature (corresponding to the subset of target features) may have different curvature. For example, an OPC feature may be fully circular, another OPC feature may only partially curved, etc. as long as portions of the mask pattern with such OPC features satisfy MRC constraints. In an embodiment, rounding of a corner of the OPC feature to satisfy the MRC constraints leaves more room to grow the mask feature to ensure the performance metric (e.g., EPE) of the patterning process is satisfied.

The method described herein and illustrated in FIG. 7-9 has several advantages over existing mask pattern generation methods. As only a portion of the initial mask pattern is modified, the computation time is much faster compared to existing methods. Also, as several of the initial mask feature shapes are maintained as rectangular shapes, the mask manufacturing process is simpler and less time consuming compared to manufacturing a fully curvilinear mask. A more consistent mask pattern can be generated compared to a free form OPC method for each target pattern having similar target features. For example, several features of an initial OPC need not be modified, so if the same target pattern appears at e.g., 100 or more different locations within a full chip layout, the OPC pattern will be substantially same.

As such, with the reduced computation time and more consistent mask features, a full chip simulation may be performed to determine a process condition for lithographic process. Such full chip simulation can be very beneficial for improving the process window of the patterning process and yield of the patterning process.

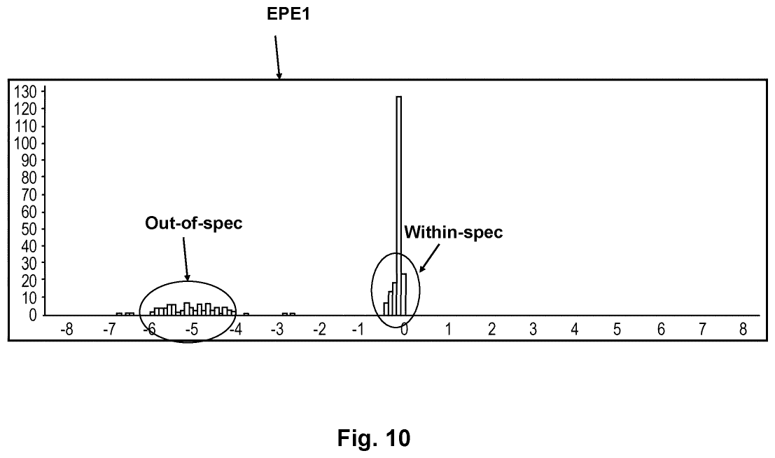

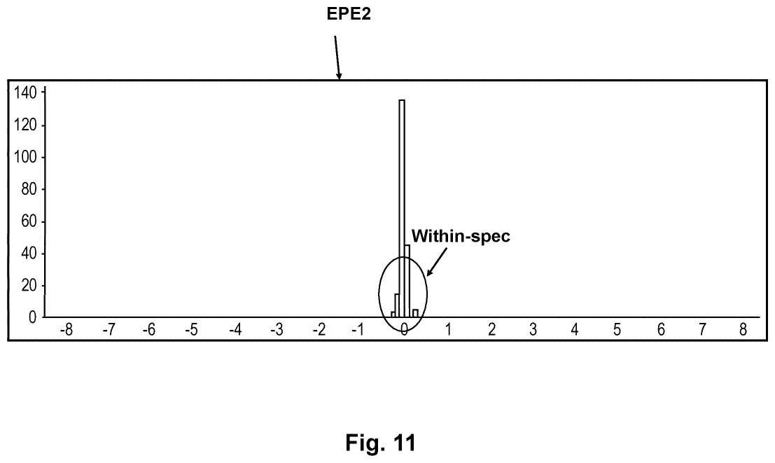

FIG. 10 and FIG. 11 show results (e.g., EPE distribution) for comparing an existing method and the present mask generation method, as discussed herein. FIG. 10 is a plot of edge placement errors corresponding to a mask pattern obtained based on the existing method. The plot shows several EPEs are within the EPE specification (e.g., within ±1 nm) and few EPEs are out of specification e.g., below −3 nm. The out-of-specification EPEs are associated with portions of target pattern having tight spaces.

FIG. 11 illustrates that upon applying the present method, the mask pattern generated e.g., having corner rounding OPC features, the resulting EPE associated with the patterning process is within 0.1 nm (i.e., within EPE specification).

In another existing method, a corner cut of certain polygon features may be employed to generate a mask pattern to improve the EPE. However, mask patterns obtained by such corner cut method causes a large variation in printed patterns on the substrate when process parameters (e.g., dose, focus) are varied. The present method provides additional benefit of having less variation in printed patterns even when process parameters vary a lot. As such, a better process window (e.g., a range of dose focus values) can be obtained compared to existing corner cut method, for example.

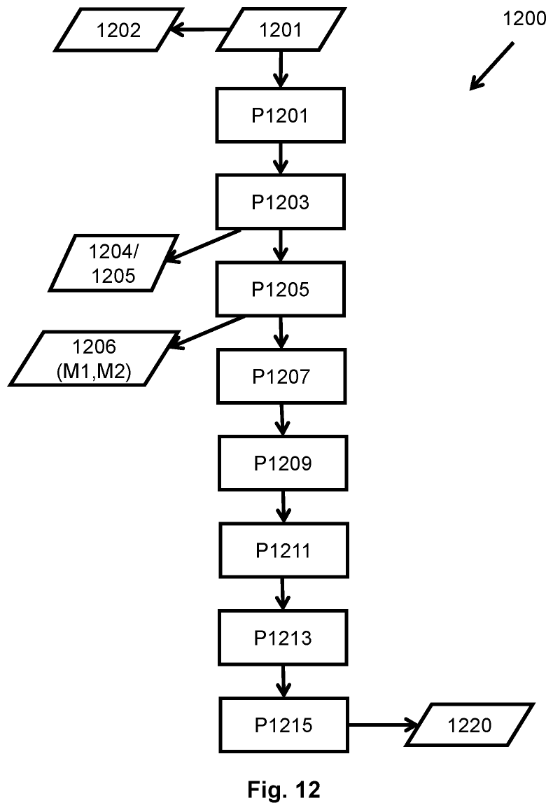

FIG. 12 is a flow chart for another implementation of a method 1200 for generating a mask pattern, according to an embodiment of the present disclosure. The method causes generation of a mask pattern for use in a semiconductor manufacturing process by applying a curvature to particular features associated with a circuit pattern so constraints related to mask manufacturing processes and patterning processes are satisfied. The method 1200 includes following processes P1201, P1203, P1205, P1207, P1209, P1211, P1213, and P1215.

Process P1201 involves receiving a desired circuit pattern 1201 (e.g., DRAM, logic, or other circuit patterns) comprising a plurality of circuit features 1202 to be printed on a substrate, each circuit feature having a polygon shape outlines. The circuit pattern 1201 may be provided in a graphic design system (e.g., GDSII) format representing planar geometric shapes of a circuit pattern. For example, a target pattern illustrate in FIG. 7 can be an example circuit pattern 1201 or a part of the circuit pattern 1201 desired to be printed on a substrate.

Process P1203 involves identifying, from the plurality of circuit features 1202, a first circuit feature 1204 and a second circuit feature 1205 that have a distance between their respective shape outlines below a distance threshold value. For example, a corner-to-corner distance between corners of rectangular polygon shapes of the circuit pattern 1201 can be below a distance threshold value. FIG. 8 shows an example features TP1 and TP2 that have tight spaces (e.g., distance less than 10 nm) between them. In an embodiment, the identifying of the first circuit feature 1204 and the second circuit feature 1205 comprises tagging the features so that during a simulation the tagged features can be modified (e.g., curved) according to the present disclosure.

Process P1205 involves determining, by simulating a process model of a patterning process using the circuit pattern 1201, an initial mask pattern 1206 associated with the circuit pattern 1201. The initial mask pattern 1206 comprises a first mask feature M1 and a second mask feature M2 corresponding to the first circuit feature 1204 and the second circuit feature 1205, respectively. The first mask feature M1 and the second mask feature M2 has polygon shape outlines different from their corresponding circuit features. For example, the polygon shapes of the initial mask pattern 1206 are rectilinear shapes (e.g., rectangular, square, pentagonal, etc.). FIG. 5B illustrates an example of the initial mask pattern 1206, which can be an intermediate result of the determining the mask pattern using e.g., OPC process.

Process P1207 involves determining whether the first mask feature M1 and the second mask feature M2 satisfy a mask manufacturing constraint. The mask manufacturing constraint comprising a criterion that limits a shape of a mask feature during the mask manufacturing process. For example, mask manufacturing constraint also referred as MRC can be a distance between two features, size of feature, etc. that can be manufactured via a mask making apparatus.

Process P1209 involves responsive to the mask manufacturing constraint not being satisfied, modifying, based on a smallest distance between outlines of the first mask feature M1 and the second mask feature M2. The initial mask pattern 1206 by applying a curvature to a portion of the first mask feature M1 and/or the second mask feature M2 causing an increase in the distance between the outlines of the first mask feature M1 and the second mask feature M2. In an embodiment, the curvature can be applied to the entire mask feature (e.g., M1 and M2). Example of mask features M1 and M2 are illustrated in FIG. 9, where features O30 and O40 are rounded.

Process P1211 involves using the modified mask pattern 1220, further simulating the process model of the patterning process to determine a simulated pattern of the patterning process. Process P1213 involves determining, by comparing the simulated pattern with the desired circuit pattern 1201, a performance metric (e.g., EPE) of the patterning process. The performance metric is indicative of how closely the simulated pattern matches the circuit pattern 1201. In an embodiment, the performance metric is an edge placement error between outlines of features of the simulated pattern and outlines of the features of the circuit pattern.

Process P1215 involves responsive to the performance metric not being within a performance threshold, applying a further curvature to the first mask feature M1 and/or the second mask feature M2 causing the performance metric to be within the within the performance threshold, while maintaining the smallest distance between outlines of the first mask feature M1 and the second mask feature M2 within the mask manufacturing constraint.

In an embodiment, features of the initial mask pattern 1206 are Manhattanized features of the target pattern, and the first mask feature M1 and/or the second mask feature M2 of the modified mask pattern 1220 are curvilinear in shape while remaining features are unchanged Manhattanized features of the initial mask pattern 1206. An example of a modified mask pattern is illustrated in FIG. 9.

In an embodiment, one or more characteristics of assist features of OPC are determined using any suitable method, based on one or more of the modified main features (e.g., O30, O40, O50 of FIG. 9). For example, the one or more characteristics of assist features may be determined using a method described in U.S. Pat. No. 9,111,062, or described Y. Shen, et al., Level-Set-Based Inverse Lithography For Photomask Synthesis, Optics Express, Vol. 17, pp. 23690-23701 (2009), the disclosures of which are hereby incorporated by reference in their entirety, and/or any other techniques described herein or in any document incorporated by reference herein.

The present disclosure has several applications. In an embodiment, the modified mask pattern 620 (e.g., modified mask pattern of FIG. 9) is provided as input into the trained machine learning model and one or more characteristics of one or more assist features for the representative patterns are obtained as output from the trained machine learning model. The one or more characteristics may include the one or more geometrical characteristics (e.g., absolute location, relative location, or shape) of the assist features. The one or more characteristics may include parameterization of the assist features, such as projection on certain basis functions. The one or more characteristics may include an image (pixelated, binary Manhattan, binary curvilinear, or continuous tone) or image data (e.g., pixel values with associated locations) of the assist features. The one or more characteristics of the assist features may be adjusted to avoid conflicts among them, for example, using a method described in U.S. Patent Application Publication No. 2008/0301620, the disclosure of which is incorporated by reference in its entirety.

In an embodiment, the method 600 may be implemented in cooperation with a method 500 that employs one or more process models to improve the patterning process. For example, to improve one or more of aspects of the patterning process such as process window, OPC, yield, etc.

In an embodiment, the mask pattern 620 comprises data corresponding to one or more characteristics of a mask to be used in a lithographic process. For example, the one or more characteristics may be geometric properties (e.g., OPC, shapes/sizes of a pattern) of the mask pattern, reflectivity of the mask, transmissivity of the mask, etc. In an embodiment, the mask pattern data comprises characteristics (e.g., OPC) upon which the patterning process adjusts one or more of process parameters including dose, focus, illumination intensity, and/or illumination pupil.

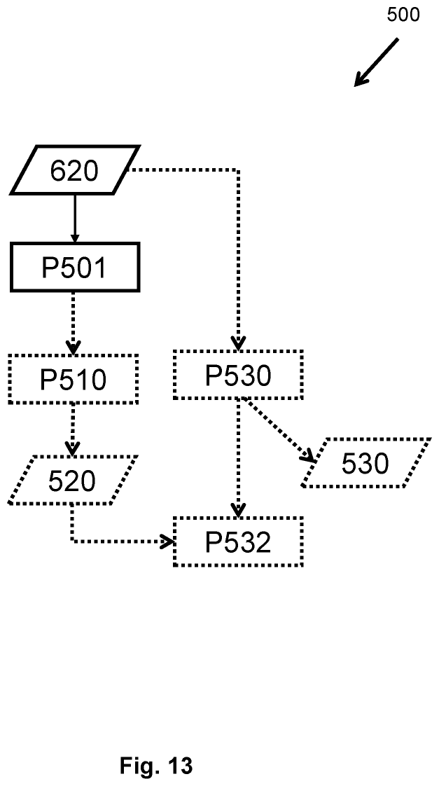

In an embodiment, the modified mask pattern 620 may be used by various entities (e.g., vendors, computer systems, etc.) associated with the patterning process. In an embodiment, the mask pattern 620 can be exported or provided in e.g., a digital form (e.g., GDS format, text file, or other appropriate format compatible with the importing entity's computer system) to a mask manufacturer. Accordingly, referring to FIG. 13, in an embodiment, process P510 involves fabricating, via a mask-making apparatus using the mask pattern 620 (e.g., including features O3, O4, O5 of FIG. 9), a mask 520 to be used in a lithographic process to image a substrate. Using the present methods, faster and more accurate mask pattern can be obtained thereby improving the mask manufacturing process and the mask produced therefrom as well. When such mask is in turn used in the patterning process, e.g., via a lithographic apparatus (e.g., FIGS. 1, 15, 16, and 17), the printed patterns will closely match the desired pattern.

In an embodiment, the mask pattern 620 may be provided as an input to a simulation of a patterning process or models associated with the patterning process. In an embodiment, a process P530 involves determining, via simulating a process model (e.g., optics model, resist model, etch model, etc.), a process condition 530 associated with a target pattern of the given design layout. In an embodiment, the process condition 530 comprises values of one or more of process parameters including dose, focus, illumination intensity, and/or illumination pupil.

Further, process P532 involves exposing, via a lithographic apparatus configured according to the process condition 530 employing the mask 520 comprising the mask pattern 620, a substrate. In an embodiment, the mask 520 is fabricated according to the process P510 discussed earlier. However, the mask 520 (or mask pattern data thereof) is not limited to a particular mask fabrication process. For example, the simulation step may receive any mask pattern data produced according existing process simulation methods (e.g., SMO, MO, etc.) as well.

According to present disclosure, the combination and sub-combinations of disclosed elements constitute separate embodiments. For example, a first combination includes generating a mask pattern by applying a curvature to selected subset of target features. The sub-combinations may include applying the curvature based on simulated contours matching target features, or based on heuristics. In another sub-combination, the curvature may be applied based on a table correlating an amount of curvature and effect on a physical characteristic (e.g., EPE, CD, etc.) on a feature on the substrate. In another example, the combination includes determining, based on the generated mask pattern, process variation bands. The process variation bands refer to changes in physical characteristics on the substrate in response to changes in process parameters (e.g., dose variation, focus variation).

As noted above, optical proximity correction modifies the design layout (of, for example, an advanced logic device) with the aim of, for example, providing sufficient process window (PW) for forming the design layout on a substrate. For example, an assist feature (as an example of OPC), particularly a SRAF, can modify the environment of isolated main features of the design layout in a manner such that the isolated features appear dense, which can enable scaling down of such main features by providing sufficient process window (PW). So, an optical proximity correction that is sufficient, accurate and consistent throughout a full-chip is desired. But, the run-time of the optical proximity correction should be fast to enable application of optical proximity correction to a full-chip in a timely manner.

Among optical proximity correction techniques, a model-based optical proximity correction approach can deliver a large process window (PW) with good accuracy and consistency, but often at the expensive of speed. For example, SMO-MO is an optical proximity correction technique that can deliver a large process window (PW). In an embodiment, SMO-MO can use a SMO process to identify an optimum illumination and patterning device pattern (which optimization may be constrained in terms of the type of OPC corrections used, e.g., no application of assist features) and then that optimum illumination is used to further optimize the patterning device pattern in terms of optical proximity correction (e.g., application of assist features). In an embodiment, SMO-MO uses a gradient-based iterative approach to optimize a continuous tone patterning device pattern so that the associated cost function is minimized/maximized In each iteration, the gradient map of the patterning device pattern is calculated and the gradient map is further used to guide the direction of the optimization (e.g., the application of OPC such as placement of assist features). SMO-MO can be highly accurate and may yield the largest process window; however the run-time can be prohibitive for full-chip applications.

Another model-based approach for optical proximity correction is use of a so-called SRAF Guidance Map (SGM) (see, e.g., U.S. Patent Application Publication No. US 2008-0301620 previously incorporated herein by reference), which is relatively faster than other approaches but can fall short on delivering an optimal process window.

Other full-chip optical proximity corrections are relatively faster than SMO-MO but each can have some disadvantages. For example, rule-based optical proximity correction approaches involve application of two-dimensional (2D) rules to apply optical proximity corrections (such as placement of assist features). But, the determination and comprehensiveness of the rules can be difficult to implement and may not guarantee accuracy of 2D rules for logic applications.

In the context of assist features, their placement typically should have accuracy less than the size of the pixels of the patterning device pattern used in the optical proximity correction process to enable the process to complete in a timely manner. For example, the accuracy should be selected from the range 0 to about 10 nm. Alternatively or additionally, consistency and/or symmetry in placement of assist features is highly desired. Consistency refers to repeating patterns in a patterning device pattern (e.g., a full chip patterning device pattern) having substantially similar assist feature placements. Assist feature placement should desirably have symmetry complying with the pattern symmetry and the illumination distribution shape symmetry (e.g., symmetry with a dipole or quadrupole illumination). But, existing techniques may not provide such accuracy, consistency and/or symmetry at a full chip level.

So, in an embodiment and as already described to some extent above with respect to FIG. 3, a machine learning process can be advantageous to enabling accurate and complete application of optical proximity correction (such as placement of assist features) and can do so in a quick manner for, e.g., full chip applications.

In an embodiment, a target pattern and an optical proximity corrected design pattern can be typically, for, e.g., manufacturing purposes, in a GDS (GDSII), OASIS or other similar format, which means they are binary. For a machine learning process, an image can be used to predict an image of the optical proximity correction. So, in an embodiment, the binary target design pattern in GDS (GDSII), OASIS or other similar format is converted to a pixelated image. In a first possibility, the target design pattern is converted into a binary pixelated image. In another possibility, the target design pattern is converted into a gray-scale pixelated image. As noted above, it can be desirable to choose the latter option—a gray-scale pixelated image. The reasons for this include, e.g.: 1) For a same given pixel size (image resolution), a gray-scale image has a significant amount more information than a binary image because of the additional degree of freedom of “continuous” intensity depending on the number of gray levels. In other words, to keep the same amount of information as a binary pixelated image, a gray-scale image can have a larger pixel size than a binary pixelated image and thus can speed up the computation; and/or 2) an advanced mask optimization engine (e.g., an SMO or iOPC software tool such ASML's Tachyon software) can directly provide a CTM image for a given target design pattern, which CTM image is in gray scale.

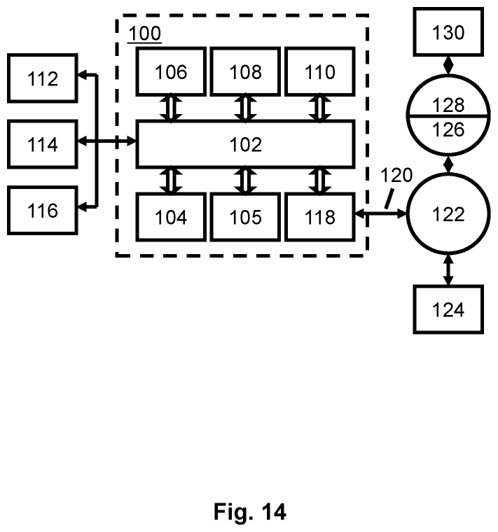

FIG. 14 is a block diagram that illustrates a computer system 100 which can assist in implementing methods and flows disclosed herein. Computer system 100 includes a bus 102 or other communication mechanism to communicate information, and a processor 104 (or multiple processors 104 and 105) coupled with bus 102 to process information. Computer system 100 may also include a main memory 106, such as a random access memory (RAM) or other dynamic storage device, coupled to bus 102 to store or supply information and instructions to be executed by processor 104. Main memory 106 may be used to store or supply temporary variables or other intermediate information during execution of instructions to be executed by processor 104. Computer system 100 may further include a read only memory (ROM) 108 or other static storage device coupled to bus 102 to store or supply static information and instructions for processor 104. A storage device 110, such as a magnetic disk or optical disk, may be provided and coupled to bus 102 to store or supply information and instructions.

Computer system 100 may be coupled via bus 102 to a display 112, such as a cathode ray tube (CRT) or flat panel or touch panel display, to display information to a computer user. An input device 114, including alphanumeric and other keys, may be coupled to bus 102 to communicate information and command selections to processor 104. Another type of user input device may be cursor control 116, such as a mouse, a trackball, or cursor direction keys, to communicate direction information and command selections to processor 104 and to control cursor movement on display 112. This input device typically has two degrees of freedom in two axes, a first axis (e.g., x) and a second axis (e.g., y), that allows the device to specify positions in a plane. A touch panel (screen) display may also be used as an input device.

According to an embodiment, portions of a process described herein may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a disk or memory of a remote computer. The remote computer can load the instructions into its dynamic memory and send the instructions over a communications path. Computer system 100 can receive the data from the path and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may include a communication interface 118 coupled to bus 102. Communication interface 118 provides a two-way data communication coupling to a network link 120 that is connected to a network 122. For example, communication interface 118 may provide a wired or wireless data communication connection. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through network 122 to a host computer 124 or to data equipment operated by an Internet Service Provider (ISP) 126. ISP 126 in turn provides data communication services through the worldwide packet data communication network, now commonly referred to as the “Internet” 128. Network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, network 122 and communication interface 118. One such downloaded application may provide for the code to implement a method herein, for example. The received code may be executed by processor 104 as it is received, or stored in storage device 110, or other non-volatile storage for later execution. In this manner, computer system 100 may obtain application code in the form of a carrier wave.

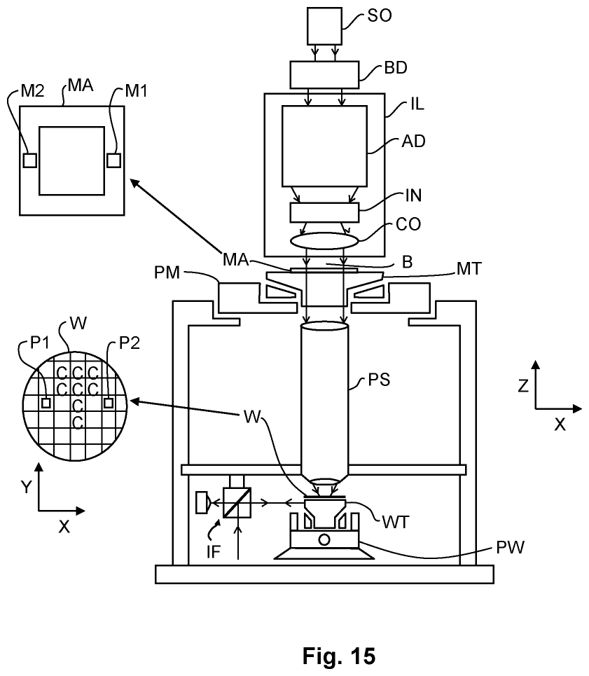

FIG. 15 schematically depicts an exemplary lithographic projection apparatus (e.g., employing a mask comprising the mask pattern generated using the method of FIG. 6). The apparatus comprises:
an illumination system IL, to condition a beam B of radiation. In this particular case, the illumination system also comprises a radiation source SO;
a first object table (e.g., mask table) MT provided with a patterning device holder to hold a patterning device MA (e.g., a reticle), and connected to a first positioner PM to accurately position the patterning device with respect to item PS;
a second object table (substrate table) WT provided with a substrate holder to hold a substrate W (e.g., a resist-coated silicon wafer), and connected to a second positioner PW to accurately position the substrate with respect to item PS;
a projection system PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive mask). However, in general, it may also be of a reflective type, for example (with a reflective mask). Alternatively, the apparatus may employ another kind of patterning device as an alternative to the use of a classic mask; examples include a programmable mirror array or LCD matrix.

The source SO (e.g., a mercury lamp or excimer laser) produces a beam of radiation. This beam is fed into an illumination system (illuminator) IL, either directly or after having traversed a conditioner, such as a beam expander. The illuminator IL may comprise an adjuster AD configured to set the outer or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 15 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors BD); this latter scenario is often the case when the source SO is an excimer laser (e.g., based on KrF, ArF or F₂ lasing).

The beam B subsequently intercepts the patterning device MA, which is held on a patterning device table MT. Having traversed the patterning device MA, the beam B passes through the projection system PS, which focuses the beam B onto a target portion C of the substrate W. With the aid of the second positioner PW (and interferometer IF), the substrate table WT can be moved accurately, e.g. so as to position different target portions C in the path of the beam B. Similarly, the first positioner PM can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 15.

Patterning device (e.g., mask) MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device (e.g., mask) MA, the patterning device alignment marks may be located between the dies. Small alignment markers may also be included within dies, in amongst the device features, in which case it is desirable that the markers be as small as possible and not require any different imaging or process conditions than adjacent features.

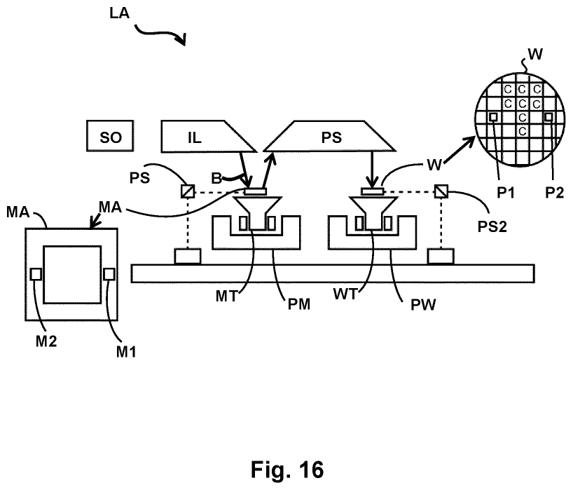

FIG. 16 schematically depicts another exemplary lithographic projection apparatus LA (e.g., employing a mask comprising a mask pattern as discussed herein). The lithographic projection apparatus LA includes:
a source collector module SO;
an illumination system (illuminator) IL configured to condition a radiation beam B (e.g. EUV radiation);
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus LA is of a reflective type (e.g. employing a reflective mask). It is to be noted that because most materials are absorptive within the EUV wavelength range, the patterning device may have a multilayer reflector comprising, for example, a multi-stack of molybdenum and silicon. In one example, the multi-stack reflector has a 40 layer pairs of molybdenum and silicon. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 16, the illuminator IL receives an extreme ultra violet (EUV) radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 16, to provide the laser beam to excite the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors or a beam expander. In other cases the source may be an integral part of the source collector module, for example when the source is a discharge produced plasma EUV generator, often termed as a DPP source.

The illuminator IL may comprise an adjuster configured to adjust the angular intensity distribution of the radiation beam. Generally, at least the outer or inner radial extent (commonly referred to as G-outer and G-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus could be used in at least one of the following modes:
1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X or Y direction so that a different target portion C can be exposed.
2. In scan mode, the support structure (e.g. mask table) MT and the substrate table WT are scanned synchronously in a given direction (the so-called “scan direction”) while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Further, the lithographic apparatus may be of a type having two or more tables (e.g., two or more substrate table, two or more patterning device tables, or a substrate table and a table without a substrate). In such “multiple stage” devices the additional tables may be used in parallel, or preparatory steps may be carried out on one or more tables while one or more other tables are being used for exposures.

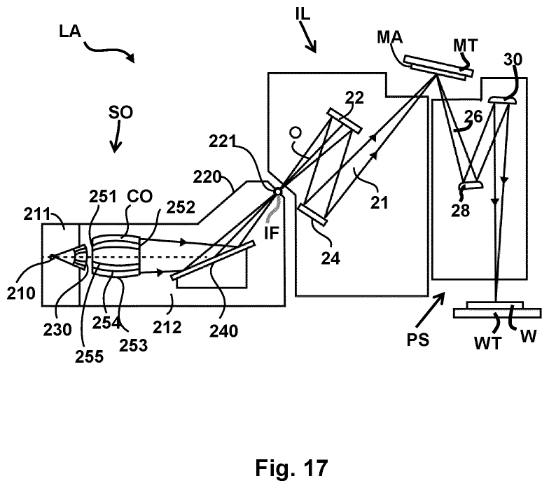

FIG. 17 shows the apparatus LA in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 17.

Collector optic CO, as illustrated in FIG. 17, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is desirably used in combination with a discharge produced plasma source, often called a DPP source.

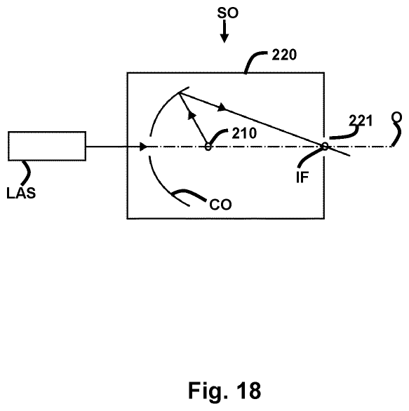

Alternatively, the source collector module SO may be part of an LPP radiation system as shown in FIG. 18. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum.

The concepts disclosed herein may be applicable to any device manufacturing process involving a lithographic apparatus, and may be especially useful with emerging imaging technologies capable of producing wavelengths of an increasingly smaller size. Emerging technologies already in use include deep ultraviolet (DUV) lithography that is capable of producing a 193 nm wavelength with the use of an ArF laser, and even a 157 nm wavelength with the use of a fluorine laser. Moreover, EUV lithography is capable of producing wavelengths within a range of 5-20 nm.

While the concepts disclosed herein may be used for device manufacturing on a substrate such as a silicon wafer, it shall be understood that the disclosed concepts may be used with any type of lithographic imaging systems, e.g., those used for imaging on substrates other than silicon wafers.

The patterning device referred to above comprises or can form a design layout. The design layout can be generated utilizing a CAD (computer-aided design) program. This process is often referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. The design rule limitations are typically referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

So, as noted, microlithography is a significant step in the manufacturing of devices such as ICs, where patterns formed on substrates define functional elements of the ICs, such as microprocessors, memory chips etc. Similar lithographic techniques are also used in the formation of flat panel displays, micro-electro mechanical systems (MEMS) and other devices.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range 5-20 nm).

The embodiments may further be described using the following clauses:
1. A non-transitory computer-readable medium for generating a mask pattern for use in a semiconductor manufacturing process by applying a curvature to particular features associated with a circuit pattern so constraints related to mask manufacturing processes and patterning processes are satisfied, the medium comprising instructions stored therein that, when executed by one or more processors, cause operations comprising:
   receiving a circuit pattern comprising a plurality of circuit features to be printed on a substrate, each circuit feature having a polygon shape outlines;
   identifying, from the plurality of circuit features, a first circuit feature and a second circuit feature that have a distance between their respective shape outlines below a distance threshold value;
   determining, by simulating a process model of a patterning process using the circuit pattern, an initial mask pattern associated with the circuit pattern, the initial mask pattern comprising a first mask feature and a second mask feature corresponding to the first circuit feature and the second circuit feature, respectively, the first mask feature and the second mask feature having polygon shape outlines different from their corresponding circuit features;
   determining whether the first mask feature and the second mask feature satisfy a mask manufacturing constraint, the mask manufacturing constraint comprising a criterion that limits a shape of a mask feature during the mask manufacturing process;
   responsive to the mask manufacturing constraint not being satisfied, modifying, based on a smallest distance between outlines of the first mask feature and the second mask feature, the initial mask pattern by applying a curvature to a portion of the first mask feature and/or the second mask feature causing an increase in the distance between the outlines of the first mask feature and the second mask feature;
   using the modified mask pattern, further simulating the process models of the patterning process to determine a simulated pattern of the patterning process;
   determining, by comparing the simulated pattern with the circuit pattern, a performance metric of the patterning process, the performance metric indicative of how closely the simulated pattern matches the circuit pattern; and
   responsive to the performance metric not being within a performance threshold, applying a further curvature to the first mask feature and/or the second mask feature causing the performance metric to be within the within the performance threshold, while maintaining the smallest distance between outlines of the first mask feature and the second mask feature within the mask manufacturing constraint.
2. The medium of clause 1, wherein:
   features of the initial mask pattern are Manhattanized features of the target pattern, and the first mask feature and/or the second mask feature of the modified mask pattern are curvilinear in shape while remaining features are unchanged Manhattanized features of the initial mask pattern.
3. A non-transitory computer-readable medium for generating a mask pattern for a patterning process comprising instructions stored therein that, when executed by one or more processors, cause operations comprising:
   obtaining (i) a subset of target features within a target pattern, the subset of target features having physical characteristic values breaching a threshold value, and (ii) an initial mask pattern associated with the target pattern; and
   modifying, based on a mask manufacturing constraint and a performance metric of the patterning process, one or more features of the initial mask pattern corresponding to the subset of target features to generate the mask pattern, the modifying comprising applying a curvature to a portion of the one or more features of the initial mask pattern.
4. The medium of clause 3, wherein the obtaining of the initial mask pattern comprises:
   simulating a mask optimization process using the target pattern to generate a mask pattern that causes a simulated pattern on a substrate to closely match the target pattern.
5. The medium of any of clauses 3-4, wherein the modifying of the initial mask pattern comprises:
   simulating the mask optimization process to modify a geometry of the one or more features of the initial mask pattern corresponding to the subset of target features.
6. The medium of clause 5, wherein the simulating of the mask optimization process is an iterative process, each iteration comprising:
   simulating, via one or more process model using the initial mask pattern, the patterning process to generate a simulated pattern on a substrate;
   determining, based on the simulated pattern and the target pattern, the performance metric associated with the patterning process;
   determining whether the performance metric is within a performance threshold; and
   modifying the geometry of the one or more features of the initial mask pattern corresponding to the subset of target features until the modified mask pattern causes the performance metric to be within the performance threshold.
7. The medium of any of clauses 4-6, wherein the mask optimization process comprises an optical proximity correction process.
8. The medium of any of clauses 3-7, wherein the performance metric comprises an edge placement error between the simulated pattern and the target pattern.
9. The medium of any of clauses 3-8, further comprising:
   determining, via simulating a process model using the mask pattern, a process condition associated the patterning process; and
   exposing, via a lithographic apparatus configured according to the process condition and employing the mask comprising the mask pattern.
10. The medium of clause 9, wherein the process condition comprises values of one or more of process parameters including dose, focus, illumination intensity, and/or illumination pupil.
11. The medium of any of clauses 3-10, wherein:
   features of the initial mask pattern are Manhattanized features of the target pattern, and the one or more features of the modified mask pattern are curvilinear in shape while
   the remaining features are unchanged Manhattanized features of the initial mask pattern.
12. The medium of any of clauses 3-10, wherein:
   features of the initial mask pattern are curvilinear in shape, and
   the one or more features of the modified mask pattern have a different curvilinear shape while remaining features are unchanged curvilinear features of the initial mask pattern.
13. The medium of any of clauses 3-12, wherein the physical characteristic comprises at least one of:
   a critical dimension of the target feature;
   a corner-to-corner distance between the target features; or
   an offset between adjacent target features.
14. A method for generating a mask pattern for a patterning process, the method comprising:
   obtaining (i) a subset of target features within a target pattern, the subset of target features having physical characteristic values below a threshold value, and (ii) an initial mask pattern associated with the target pattern; and
   modifying, based on a mask manufacturing constraint and a performance metric of the patterning process, one or more features of the initial mask pattern corresponding to the subset of target features to generate the mask pattern, the modifying comprising applying a curvature to a portion of the one or more features of the initial mask pattern.
15. The method of clause 14, wherein the obtaining of the initial mask pattern comprises:
   simulating a mask optimization process using the target pattern to generate a mask pattern that causes a simulated pattern on a substrate to closely match the target pattern.
16. The method of any of clauses 14-15, wherein the modifying of the initial mask pattern comprises:
   simulating the mask optimization process to modify a geometry of the one or more features of the initial mask pattern corresponding to the subset of target features.
17. The method of clause 16, wherein the simulating of the mask optimization process is an iterative process, each iteration comprising:
   simulating, via one or more process model using the initial mask pattern, the patterning process to generate a simulated pattern on a substrate;
   determining, based on the simulated pattern and the target pattern, the performance metric associated with the patterning process;
   determining whether the performance metric is within a performance threshold; and
   modifying the geometry of the one or more features of the initial mask pattern corresponding to the subset of target features until the modified mask pattern causes the performance metric to be within the performance threshold.
18. The method of any of clauses 15-17, wherein the mask optimization process comprises an optical proximity correction process.
19. The method of any of clauses 14-18, wherein the performance metric comprises an edge placement error between the simulated pattern and the target pattern.
20. The method of any of clauses 14-19, further comprising:
   determining, via simulating a process model using the mask pattern, a process condition associated the patterning process; and
   exposing, via a lithographic apparatus configured according to the process condition and employing the mask comprising the mask pattern.
21. The method of clause 20, wherein the process condition comprises values of one or more of process parameters including dose, focus, illumination intensity, and/or illumination pupil.
22. The method of any of clauses 14-21, wherein:
   features of the initial mask pattern are Manhattanized features of the target pattern, and
   the one or more features of the modified mask pattern are curvilinear in shape while the remaining features are unchanged Manhattanized features of the initial mask pattern.
23. The method of any of clauses 14-21, wherein:
   features of the initial mask pattern are curvilinear in shape, and
   the one or more features of the modified mask pattern have a different curvilinear shape while remaining features are unchanged curvilinear features of the initial mask pattern.
24. The method of any of clauses 14-23, wherein the physical characteristic comprises at least one of:
   a critical dimension of the target feature;
   a corner-to-corner distance between the target features; or
   an offset between adjacent target features.

The term “optimizing” and “optimization” as used herein refers to or means adjusting a patterning process apparatus, one or more steps of a patterning process, etc. such that results and/or processes of patterning have more desirable characteristics, such as higher accuracy of transfer of a design layout on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures. For example, this technology may be structured for cloud computing whereby a single function is shared and processed in collaboration among a plurality of apparatuses via a network.

1. A non-transitory computer-readable medium comprising instructions stored therein that, when executed by one or more processors, are configured to cause the one or more processors to at least:
obtain (i) a subset of target features within a target pattern, the subset of target features having physical characteristic values breaching a threshold value, and (ii) an initial mask pattern associated with the target pattern; and
modify, based on a mask manufacturing constraint and a performance metric of a patterning process, one or more features of the initial mask pattern corresponding to the subset of target features to generate a mask pattern for the patterning process, the modification comprising application of a curvature to a portion of the one or more features of the initial mask pattern.

2. The medium of claim 1, wherein the instructions configured to cause the one or more processors to obtain the initial mask pattern are further configured to cause the one or more processors to use the target pattern to generate a mask pattern that causes a simulated pattern on a substrate to closely match the target pattern.

3. The medium of claim 1, wherein the instructions configured to cause the one or more processors to modify of the initial mask pattern are further configured to cause the one or more processors to modify a geometry of the one or more features of the initial mask pattern corresponding to the subset of target features.

4. The medium of claim 3, wherein the modification of the initial mask pattern is an iterative process, each iteration comprising:
simulation, via one or more process models using the initial mask pattern, of the patterning process to generate a simulated pattern on a substrate;
determination, based on the simulated pattern and the target pattern, of the performance metric associated with the patterning process;
determination of whether the performance metric is within a performance threshold; and
modification of the geometry of the one or more features of the initial mask pattern corresponding to the subset of target features until the modified mask pattern causes the performance metric to be within the performance threshold.

5. The medium of claim 2, wherein the generation of the mask pattern comprises an optical proximity correction process.

6. The medium of claim 1, wherein the performance metric comprises an edge placement error between a simulated pattern and the target pattern.

7. The medium of claim 1, wherein the instructions are further configured to cause the one or more processors to:
determine, via simulating using a process model and the mask pattern, a process condition associated with the patterning process; and
enable exposure, via a lithographic apparatus configured according to the process condition and employing a mask comprising the mask pattern.

8. The medium of claim 7, wherein the process condition comprises a value of one or more selected from: dose, focus, illumination intensity, and/or illumination pupil.

9. The medium of claim 1, wherein features of the initial mask pattern are Manhattanized features of the target pattern, and the one or more features of the modified mask pattern are curvilinear in shape while the remaining features are unchanged Manhattanized features of the initial mask pattern.

10. The medium of claim 1, wherein features of the initial mask pattern are curvilinear in shape, and the one or more features of the modified mask pattern have a different curvilinear shape while remaining features are unchanged curvilinear features of the initial mask pattern.

11. The medium of claim 1, wherein the physical characteristic comprises at least one selected from:
a critical dimension of the target feature;
a corner-to-corner distance between the target features; or
an offset between adjacent target features.

12. (canceled)

13. A method comprising:
obtaining (i) a subset of target features within a target pattern, the subset of target features having physical characteristic values breaching a threshold value, and (ii) an initial mask pattern associated with the target pattern; and
modifying, based on a mask manufacturing constraint and a performance metric of a patterning process, one or more features of the initial mask pattern corresponding to the subset of target features to generate a mask pattern for the patterning process, the modifying comprising applying a curvature to a portion of the one or more features of the initial mask pattern.

14. The method of claim 13, wherein obtaining the initial mask pattern comprises using the target pattern to generate a mask pattern as the initial mask pattern that causes a simulated pattern on a substrate to closely match the target pattern.

15. The method of claim 13, wherein the performance metric comprises an edge placement error between a simulated pattern and the target pattern.

16. The method of claim 13, further comprising:
determining, using the mask pattern, a process condition associated with the patterning process; and
exposing a substrate, via a lithographic apparatus configured according to the process condition and employing a mask comprising the mask pattern.

17. The method of claim 13, wherein features of the initial mask pattern are Manhattanized features of the target pattern, and the one or more features of the modified mask pattern are curvilinear in shape while the remaining features are unchanged Manhattanized features of the initial mask pattern.

18. The method of claim 13, wherein features of the initial mask pattern are curvilinear in shape, and the one or more features of the modified mask pattern have a different curvilinear shape while remaining features are unchanged curvilinear features of the initial mask pattern.

19. A non-transitory computer-readable medium comprising instructions stored therein that, when executed by one or more processors, are configured to cause the one or more processors to at least:
determine, by simulation, an initial mask pattern associated with a circuit pattern, the initial mask pattern comprising a first mask feature and a second mask feature corresponding to a first circuit feature and a second circuit feature, respectively, the first mask feature and the second mask feature having polygon shape outlines different from their corresponding circuit features;
determine whether the first mask feature and the second mask feature satisfy a mask manufacturing constraint, the mask manufacturing constraint comprising a criterion that limits a shape of a mask feature during the mask manufacturing process;
responsive to the mask manufacturing constraint not being satisfied, modify, based on a smallest distance between outlines of the first mask feature and the second mask feature, the initial mask pattern by applying a curvature to a portion of the first mask feature and/or the second mask feature causing an increase in the distance between the outlines of the first mask feature and the second mask feature.

20. The medium of claim 19, wherein the instructions are further configured to cause the one or more processors to:
using the modified mask pattern, determine a simulated pattern of the patterning process;
determine, by comparing the simulated pattern with the circuit pattern, a performance metric of the patterning process, the performance metric indicative of how closely the simulated pattern matches the circuit pattern; and
responsive to the performance metric not being within a performance threshold, apply a further curvature to the first mask feature and/or the second mask feature causing the performance metric to be within the within the performance threshold, while maintaining the smallest distance between outlines of the first mask feature and the second mask feature within the mask manufacturing constraint.

21. The medium of claim 19, wherein the instructions are further configured to cause the one or more processors to:
receive the circuit pattern, the circuit pattern comprising a plurality of circuit features to be printed on a substrate, each circuit feature having a polygon shape outline; and
identify, from the plurality of circuit features, the first circuit feature and the second circuit feature that have a distance between their respective shape outlines below a distance threshold value.
